(19) United States
(12) Patent Application Publication
(10) Pub. No.: US 2025/0221119 A1
(43) Pub. Date: Jul. 3, 2025

(54) DISPLAY DEVICE AND METHOD OF FABRICATING THE SAME

(71) Applicant: LG Display Co., Ltd., Seoul (KR)

(72) Inventors: Won Ki PARK, Paju-si (KR); Sang Wook WOO, Paju-si (KR); Min Wan KIM, Paju-si (KR)

(21) Appl. No.: 18/886,618

(22) Filed: Sep. 16, 2024

(30) Foreign Application Priority Data
Dec. 28, 2023 (KR) 10-2023-0194687

(51) Int. Cl. H01L 33/62; H01L 25/075; H01L 25/16; H01L 33/00

(52) U.S. Cl. CPC H10H 20/857; H01L 25/167; H10H 20/01; H01L 25/0753; H10H 20/0364

(57) ABSTRACT

Various embodiments of a display device and a method of fabricating the same are disclosed. A display device includes a substrate. The display device includes an electrode disposed on the substrate. The display device includes a bonding pattern disposed on the electrode and including conductive particles with an aspect ratio of 50 or more. The display device includes a light-emitting element disposed on the bonding pattern and electrically connected to the electrode.

### CROSS-REFERENCE TO RELATED APPLICATION

This application claims priority to and the benefit of Korean Patent Application No. 2023-0194687, filed on Dec. 28, 2023, the disclosure of which is incorporated herein by reference in its entirety.

### BACKGROUND

### Technical Field

The present specification relates to a display device, and more specifically, to a display device and a method of fabricating the same.

### Description of Related Art

An electroluminescent display device includes an organic light-emitting display device in which an organic light-emitting diode (OLED) is disposed and an inorganic light-emitting display device (hereinafter referred to as “LED display device”) in which an inorganic light-emitting diode (hereinafter referred to as “LED”) is disposed.

The electroluminescent display device displays images using self-luminous elements, and thus does not require a separate light source, for example, a backlight unit, and can be implemented in various thin forms.

Recently, as an example of the inorganic light-emitting display device, a micro LED display device in which micro light-emitting diodes (micro-LEDs) are disposed in pixels has been attracting attention as a next-generation display device.

A micro light-emitting element (μ-LED) means a micro inorganic light-emitting element having a size of 100 μm or less. When the micro light-emitting element is used as a pixel, miniaturization and lightening of the device are possible.

### BRIEF SUMMARY

In order to fabricate a display device using a micro light-emitting element, the micro light-emitting element is crystallized on a substrate made of sapphire or silicon, and the crystallized micro light-emitting element is transferred to the substrate with a driving circuit and connected to the substrate.

The present specification is directed to providing a display device which allows an electronic component including a light-emitting element with a narrow electrode spacing to be mounted by improving the connection reliability of microelectrodes of a light-emitting element, and a method of fabricating the same.

The technical problems of the present specification are not limited to the above-mentioned technical problems, and other technical problems which are not mentioned will be clearly understood by those skilled in the art from the following description.

A display device according to one embodiment of the present specification includes a substrate, an electrode disposed on the substrate, a bonding pattern disposed on the electrode and including conductive particles with an aspect ratio of 50 or more, and a light-emitting element disposed on the bonding pattern and electrically connected to the electrode.

A method of fabricating a display device according to one embodiment of the present specification includes forming an electrode on a substrate, forming a bonding pattern including conductive particles with an aspect ratio of 50 or more on the electrode, and disposing a light-emitting element on the bonding pattern and electrically connecting the light-emitting element to the electrode.

### BRIEF DESCRIPTION OF THE SEVERAL VIEWS OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a view illustrating a display device according to the present specification;

FIG. 2 is an enlarged view of region A in FIG. 1;

FIG. 3 is a view illustrating a partial region of a pixel;

FIG. 4 is a cross-sectional view taken along line I-I′ in FIG. 3;

FIG. 5 is a cross-sectional view taken along line II-II′ in FIG. 3;

FIG. 6 is an enlarged view of region B in FIG. 5;

FIG. 7 is a cross-sectional view illustrating a substrate connection structure of a light-emitting element constituting the display device according to one embodiment of the present specification;

FIG. 8 is an enlarged cross-sectional view illustrating a bonding pattern in the substrate connection structure of the light-emitting element constituting the display device according to one embodiment of the present specification;

FIGS. 9A-9C are views illustrating an alignment and orientation state of conductive particles in the bonding pattern of FIG. 8, wherein FIG. 9A is a view illustrating a perfectly vertically aligned state (S=1), FIG. 9B is a view illustrating an aligned state in a vertical direction at a certain angle (θ)(0<S<1), and FIG. 9C is a view illustrating an unaligned state (S=0);

FIG. 10 is an enlarged cross-sectional view illustrating a bonding pattern in a substrate connection structure of a light-emitting element constituting a display device according to another embodiment of the present specification;

FIGS. 11A to 11F are views illustrating a substrate connection process of light-emitting elements constituting a display device according to one embodiment of the present specification;

FIG. 12 is a view illustrating the connection resistance according to materials constituting a bonding pattern in a substrate connection structure of the display device according to one embodiment of the present specification; and

FIG. 13 is a view illustrating the connection resistance according to the content of conductive particles of the bonding pattern in the substrate connection structure of the display device according to one embodiment of the present specification.

### DETAILED DESCRIPTION

Advantages and features of the present specification, and methods of achieving them will become apparent with reference to the following embodiments, which are described in detail, in conjunction with the accompanying drawings. The present specification is not limited to the embodiments to be described below and may be implemented in various different forms, the embodiments are only provided to completely disclose the present specification and completely convey the scope of the present specification to those skilled in the art.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Further, in describing the present specification, when it is determined that a detailed description of related known technology may unnecessarily obscure the gist of the present specification, the detailed description thereof will be omitted.

When ‘providing,’ ‘including,’ ‘having,’ ‘consisting of,’ and the like mentioned in the present specification are used, other parts may be added unless ‘only’ is used. A case where a component is expressed in a singular form includes a plural form unless explicitly stated otherwise.

In interpreting the components, it should be understood that an error range is included even when there is no separate explicit description.

In the case of a description of a positional relationship, for example, when the positional relationship of two parts is described as ‘on,’ ‘at an upper portion,’ ‘at a lower portion,’ ‘on a side surface and the like, one or more other parts may be located between the two parts unless ‘immediately’ or ‘directly’ is used.

A case where an element or a layer is described as being on another element or layer includes both cases in which the element or layer is directly on the other element or layer and cases in which still another layer or element is interposed between the other element or layer and the element or layer.

Further, although first, second, and the like are used to describe various components, these components are not limited by these terms. These terms are only used to distinguish one component from another component. Accordingly, a first component to be mentioned below may also be a second component within the technical spirit of the present specification.

The same reference numerals refer to the same components throughout the specification.

Features of various embodiments of the present specification may be partially or entirely coupled to or combined with each other, and technically, various types of interconnections and driving are possible, and the embodiments may be implemented independently of each other or may be implemented together in a related relationship.

Hereinafter, various embodiments of the present specification will be described in detail with reference to the accompanying drawings.

A display device according to one embodiment of the present specification includes a display region where an image is displayed or a display panel on which a screen is disposed, and a pixel driving circuit which drives pixels of the display panel. The display region includes a pixel region where the pixels are disposed. The pixel region includes a plurality of light-emitting regions. A light-emitting element is disposed in each of the light-emitting regions. The pixel driving circuit may be built in the display panel.

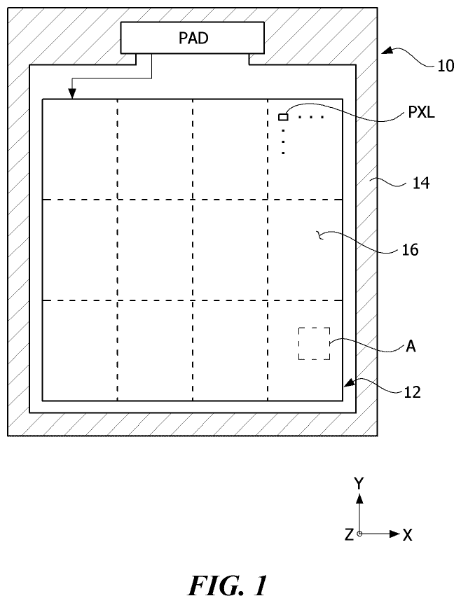

FIG. 1 is a view illustrating a display device according to one embodiment of the present specification.

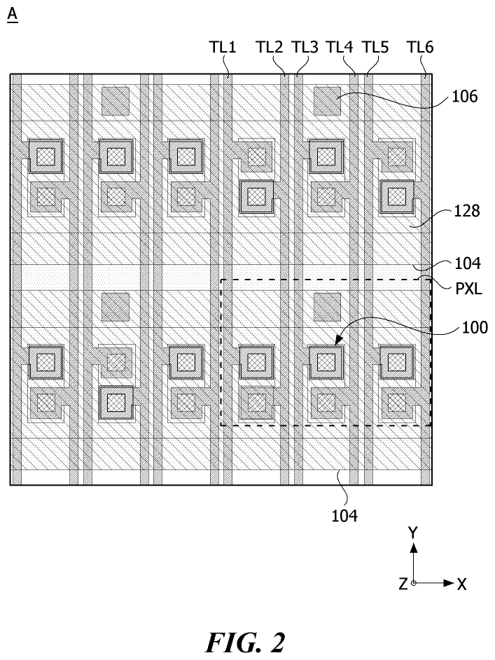

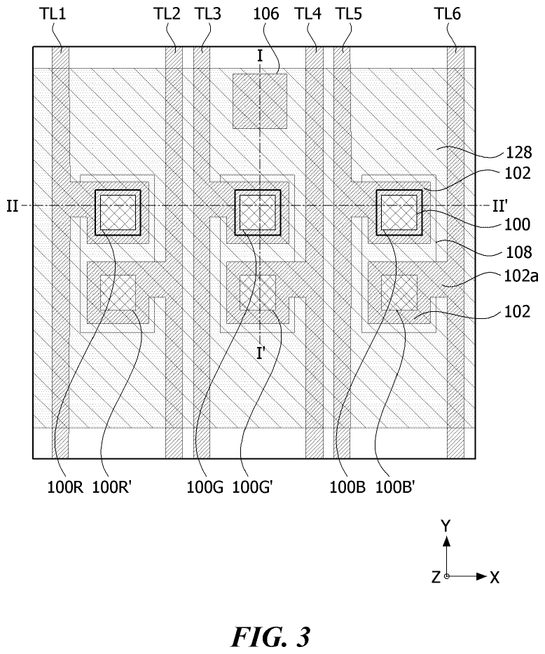

FIG. 2 is an enlarged view of region A in FIG. 1. FIG. 3 is a view illustrating a partial region of a pixel.

Referring to FIGS. 1 and 2, a display device 10 according to an embodiment of the present specification includes a display panel where an input image is visually reproduced. The display panel may include a display region 12 where an image is displayed and a non-display region 14 where the image is not displayed. In the non-display region 14, various lines and driving circuits may be mounted, and a pad portion PAD to which an integrated circuit, a printed circuit, and the like are connected may be disposed.

A plurality of light-emitting elements 100 disposed in the display region 12 and forming pixels PXL may be micro-sized inorganic light-emitting elements. The inorganic light-emitting elements may be grown on a silicon wafer and then attached to the display panel through a transfer process.

Referring to FIGS. 1 to 3, a transfer process of the light-emitting elements 100 may be performed for each previously divided region. In FIG. 1, an example in which the display region 12 is divided into twelve transfer regions 16 is described, but the size of the transfer region or the number of divided transfer regions is not limited thereto. The transfer process may be performed sequentially or simultaneously on a first transfer region 16 to a twelfth transfer region 16. Red light-emitting elements 100R and 100R′, green light-emitting elements 100G and 100G′, and blue light-emitting elements 100B and 100B′ may be sequentially transferred to each transfer region 16.

In the non-display region 14, data driving circuits or gate driving circuits may be disposed, and lines to which control signals for controlling these driving circuits are supplied may be disposed. Here, the control signals may include various timing signals including a clock signal, an input data enable signal, and a synchronization signal and may be received through the pad portion PAD.

The pixels PXL may be driven by the pixel driving circuit. The pixel driving circuit may receive a driving voltage, an image signal (digital signal), a synchronization signal synchronized with the image signal, and the like and output an anode voltage and a cathode voltage of the light-emitting element 100 to drive a plurality of pixels. The driving voltage may be a high-potential voltage EVDD. The cathode voltage may be a low-potential voltage EVSS applied to the pixels in common. The anode voltage may be a voltage corresponding to a pixel data value of the image signal. The pixel driving circuit may be disposed in the non-display region 14 or under the display region 12.

Each of the pixels PXL may include a plurality of sub-pixels having different colors. For example, each of the plurality of pixels may include a red sub-pixel where the light-emitting element 100 which emits red wavelength light is disposed, a green sub-pixel where the light-emitting element 100 which emits green wavelength light is disposed, and a blue sub-pixel where the light-emitting element 100 which emits blue wavelength light is disposed. The plurality of pixels may further include a white pixel.

Referring to FIGS. 2 and 3, the plurality of pixels PXL may be continuously disposed in a first direction (X-axis direction) and a second direction (Y-axis direction). A plurality of sub-pixels of the same color may be disposed in the pixel of the display region 12. For example, each of the plurality of pixels may include a first red sub-pixel where a 1-1 light-emitting element 100R which emits red wavelength light is disposed, a second red sub-pixel where a 1-2 light-emitting element 100R′ which emits red wavelength light is disposed, a first green sub-pixel where a 2-1 light-emitting element 100G which emits green wavelength light is disposed, a second green sub-pixel where a 2-2 light-emitting element 100G′ which emits green wavelength light is disposed, a first blue sub-pixel where a 3-1 light-emitting element 100B which emits blue wavelength light is disposed, and a second blue sub-pixel where a 3-2 light-emitting element 100B′ which emits blue wavelength light is disposed. The 1-1 light-emitting element 100R, the 2-1 light-emitting element 100G, and the 3-1 light-emitting element 100B may be interpreted as main light-emitting elements. The 1-2 light-emitting element 100R′, the 2-2 light-emitting element 100G′, and the 3-2 light-emitting element 100B′ may be interpreted as sub light-emitting elements.

Since one sub-pixel includes at least one or more light-emitting elements, the brightness of the sub-pixel may be adjusted by increasing the brightness of the other light-emitting elements when one light-emitting element becomes defective. However, the present specification is not necessarily limited thereto, and one sub-pixel may include only one light-emitting element.

A plurality of first electrodes 102 may be respectively disposed under the light-emitting elements 100 and may be selectively connected to a plurality of signal lines TL1 to TL6 through a connection portion 102a. A high-potential voltage may be applied to the pixel driving circuit through the signal lines TL1 to TL6. The signal lines TL1 to TL6 and the first electrodes 102 may be formed as an integrated electrode pattern in an electrode patterning process.

For example, a first signal line TL1 may be connected to an anode electrode of the first red sub-pixel, and a second signal line TL2 may be connected to an anode electrode of the second red sub-pixel. A third signal line TL3 may be connected to an anode electrode of the first green sub-pixel, and a fourth signal line TL4 may be connected to an anode electrode of the second green sub-pixel. A fifth signal line TL5 may be connected to an anode electrode of the first blue sub-pixel, and a sixth signal line TL6 may be connected to an anode electrode of the second blue sub-pixel. When one sub-pixel includes only one light-emitting element, the number of signal lines TL may be reduced by half.

A second electrode 104 may be a cathode electrode that is disposed in each row and applies a cathode voltage to the light-emitting elements 100 continuously disposed in the first direction (the X-axis direction). A plurality of second electrodes 104 may be disposed to be spaced apart from each other in the second direction (the Y-axis direction). The plurality of second electrodes 104 may be connected to the cathode voltage through a contact electrode 106. Each of the plurality of second electrodes 104 may be electrically connected to the contact electrode 106. However, the present specification is not necessarily limited thereto, and the second electrode 104 may not be divided into the plurality of second electrodes 104 and may be configured as one electrode layer and function as a common electrode.

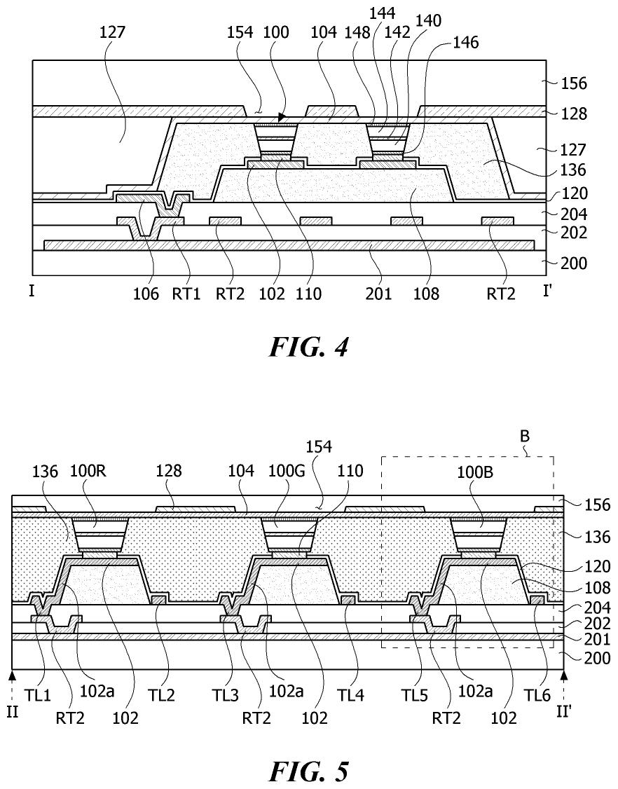

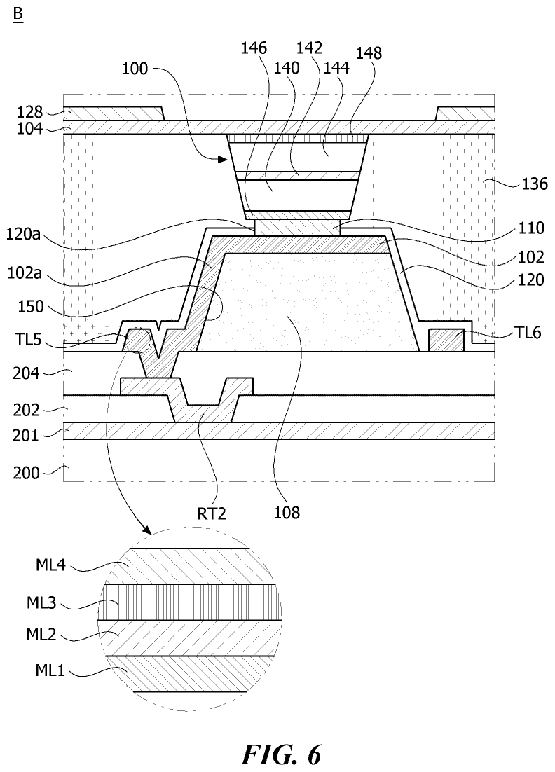

FIG. 4 is a cross-sectional view taken along line I-I′ in FIG. 3. FIG. 5 is a cross-sectional view taken along line II-II′ in FIG. 3. FIG. 6 is an enlarged view of region B in FIG. 5.

Referring to FIGS. 4 to 6, the display device according to the embodiment of the present specification includes the plurality of first electrodes 102 and the contact electrode 106 disposed on a substrate 200, the plurality of light-emitting elements 100 disposed on the plurality of first electrodes 102, a first optical layer 136 disposed between the plurality of light-emitting elements 100, and the second electrode 104 disposed on the plurality of light-emitting elements 100 and the first optical layer 136.

The substrate 200 may be composed of plastic having flexibility. For example, the substrate 200 may be fabricated as a single-layer or multi-layer substrate composed of a material selected from polyimide, polyethylene terephthalate, polyethylene naphthalate, polycarbonate, polyethersulfone, polyarylate, polysulfone, and a cyclic-olefin copolymer, but is not limited thereto. For example, the substrate 200 may be a ceramic substrate or glass substrate.

A pixel driving circuit 201 may be disposed on the substrate 200 in the display region 12. The pixel driving circuit 201 may include a plurality of thin film transistors using an amorphous silicon semiconductor, a polycrystalline silicon semiconductor, or an oxide semiconductor.

The pixel driving circuit 201 may include at least one driving thin film transistor, at least one switching thin film transistor, and at least one storage capacitor. The pixel driving circuit 201 may be formed on the substrate 200 through a process of fabricating a thin film transistor (TFT) when including a plurality of thin film transistors. In the embodiment, the pixel driving circuit 201 may be a concept that collectively refers to a plurality of thin film transistors electrically connected to the light-emitting elements 100.

The pixel driving circuit 201 may be a driving driver fabricated on a single crystal semiconductor substrate 200 using a process of fabricating a metal-oxide-silicon field effect transistor (MOSFET). The driving driver may include a plurality of pixel driving circuits to drive a plurality of sub-pixels. When the pixel driving circuit 201 is implemented as a driving driver, after an adhesive layer is disposed on the substrate 200, the driving driver may be mounted on the adhesive layer through a transfer process.

A buffer layer 202 which covers the pixel driving circuit 201 may be disposed on the substrate 200. The buffer layer 202 may be composed of an organic insulating material, for example, photosensitive photo acryl or photosensitive polyimide, but is not limited thereto.

An insulating layer 204 may be disposed on the buffer layer 202. The insulating layer 204 may be composed of an organic insulating material, for example, photosensitive photo acryl or photosensitive polyimide, but is not limited thereto.

Connection lines may be disposed on the buffer layer 202. The connection lines may include a plurality of connection lines such as a first connection line RT1, a second connection line RT2, and the like. The connection lines may be connected to the corresponding signal lines TL1 to TL6 or connected to signal lines TL. The signal lines may include the first signal line TL1 to the sixth signal line TL6, but are not limited thereto. The connection lines may include a plurality of line patterns disposed on different layers with one or more insulating layers interposed therebetween. The line patterns disposed on different layers may be electrically connected through contact holes passing through the insulating layer.

A plurality of bank patterns 108 may be disposed on the insulating layer 204. At least one light-emitting element 100 may be disposed on each bank pattern 108.

The bank pattern 108 may be composed of an organic insulating material, for example, photosensitive photo acryl or photosensitive polyimide, but is not limited thereto. The bank pattern 108 may guide a position where the light-emitting element 100 will be attached in the transfer process of the light-emitting elements 100. The bank pattern 108 may also be omitted.

A bonding pattern 110 may be disposed on the first electrode 102. The bonding pattern 110 may include a plurality of conductive particles including a conductive particle material with a large aspect ratio and a photosensitive resin to improve the connection reliability between a first driving electrode 146 which is a lower electrode of the light-emitting element 100 and the first electrode 102 of the substrate.

The photosensitive resin includes a binder, and the binder may include negative type and positive type binders.

The conductive particles may include a conductive filler and a conductive particle material with a large aspect ratio or may include a conductive particle material with a large aspect ratio.

Here, the conductive filler may include metal-based or carbon-based conductive materials. The metal-based conductive materials may include a CNT, Ag, an Ag nanowire, and the like. However, the present specification is not limited thereto. The carbon-based conductive materials may include spherical carbon black, carbon nanotubes, carbon fibers, and graphene. However, the present specification is not limited thereto.

The conductive particle with a large aspect ratio may include a conductive particle material with an aspect ratio of 50 to 1000 or more. Specifically, in some embodiments, it may be preferable to have the conductive particles including conductive particle materials with an aspect ratio of 300 to 500 or more. Further, the materials with an aspect ratio of 300 to 500 or more include a carbon fiber and an Ag nanowire. However, the present specification is not limited thereto.

Further, about 3 wt % or more, and preferably, 5 wt % or more of the conductive particle may be contained in the bonding pattern 110.

Each of the plurality of light-emitting elements 100 may be mounted on the bonding pattern 110.

One pixel may include light-emitting elements 100 of three colors. For example, the light-emitting element 100 may include a red, green, or blue light-emitting element. Two light-emitting elements may be mounted in each sub-pixel.

The first optical layer 136 may cover the side surfaces of the plurality of light-emitting elements 100 and the bank patterns 108. Accordingly, the first optical layer 136 may cover a space between the plurality of light-emitting elements 100 and a space between the plurality of bank patterns 108. The first optical layers 136 may extend in the first direction (X) and may be spaced apart in the second direction (Y) to be separated between pixel rows.

The first optical layer 136 may include an organic insulating material in which fine metal particles such as titanium dioxide particles are dispersed. Light emitted from the plurality of light-emitting elements 100 may be dispersed in the first optical layer 136, scattered by the fine metal particles, and emitted to the outside.

The second electrode 104 may be disposed on the plurality of light-emitting elements 100. The second electrode 104 may be connected to the plurality of pixels PXL in common. The second electrode 104 may be a thin electrode which transmits light. The second electrode 104 may be a transparent electrode material, for example, indium tin oxide (ITO), but is not necessarily limited thereto.

The second electrodes 104 may extend in the first direction (the X-axis direction) and may be spaced apart in the second direction (the Y-axis direction). Each of the plurality of second electrodes 104 may overlap the first optical layer 136 on a plane and may cover an outer plane of the first optical layer 136.

A second optical layer 127 may be an organic insulating material on the second electrode 104. The second optical layer 127 may include the same material as the first optical layer 136 (for example, siloxane). However, the present specification is not necessarily limited thereto, and the first optical layer 136 and the second optical layer 127 may be formed of the same material or may be formed of different materials.

The second optical layer 127 may cover a portion of an upper portion of the second electrode 104. That is, the first optical layer 136 and the second optical layer 127 may function as planarization layers. Accordingly, since there is no step on a surface where a black matrix 128 is formed, a pattern of the black matrix 128 may be easily formed on the second electrode 104 and the second optical layer 127. However, the present specification is not necessarily limited thereto, and upper surfaces of the second optical layer 127 and the second electrode 104 may have different heights.

The black matrix 128 may be an organic insulating material to which a black pigment is added.

The second electrode 104 may be in contact with the contact electrode 106 under the black matrix 128. Transmission holes 154 through which light emitted from the light-emitting elements 100 is emitted to the outside may be formed between the patterns of the black matrix 128. The transmission holes 154 may overlap the light-emitting elements 100 in a Z-axis direction, and a partial region of the black matrix 128 may overlap the first optical layer 136 in the Z-axis direction. Here, the Z-axis direction may be referred to as a third direction.

Accordingly, the black matrix 128 may improve the problem in which light emitted from each of the neighboring light-emitting elements 100 is mixed by the first optical layer 136 and then emitted.

A 1-2 optical layer (not shown) having the same material as the first optical layer 136 may be additionally disposed between the black matrix 128 and the second electrode 104. The 1-2 optical layer serves to increase the efficiency of light emitted to the front.

A cover layer 156 may be an organic insulating material which covers the black matrix 128 and the second electrode 104. The contact electrode 106 may be electrically connected to the first connection line RT1 disposed thereunder, and the first connection line RT1 may be connected to the pixel driving circuit 201.

Accordingly, a cathode voltage may be applied to the second electrode 104 through the contact electrode 106. The first electrode 102 may be electrically connected to the second connection line RT2. This will be described below.

The contact electrode 106 and the signal lines TL1 to TL6 may be disposed on the same plane. The pixel driving circuit 201 may be disposed under the contact electrode 106 and the signal lines TL1 to TL6. When the pixel driving circuit 201 is a driving driver, a plurality of driving drivers may be disposed in the display panel.

A passivation layer 120 may expose the contact electrode 106 so that the contact electrode 106 and the second electrode 104 are electrically connected. Further, the passivation layer 120 may insulate the signal lines TL2 to TL5 and the second electrode 104.

Referring to FIG. 6, the connection portion 102a of the first electrode 102 may extend along one side surface 150 of the bank pattern 108 to be disposed on the insulating layer 204 and may be electrically connected to the second connection line RT2.

The first electrode 102, the connection portion 102a, the signal lines TL, and/or the connection lines RT1 and RT2 may include a single layer or multi-layer metal layer selected from titanium (Ti), molybdenum (Mo), and aluminum (Al).

The first electrode 102 or the signal lines TL may be formed to have a metal stack structure in which a plurality of metal layers is formed using metal materials having different materials, thicknesses, and the like. In this case, the first electrode 102, the connection portion 102a, and the signal lines TL may be formed simultaneously through the same fabrication process. Here, the thickness may mean a width between one side and the other side of the metal layer disposed in the Z direction.

The first electrode 102 may include a first metal layer ML1 disposed under the bonding pattern 110, a second metal layer ML2 disposed under the first metal layer ML1, a third metal layer ML3 disposed under the second metal layer ML2, and a fourth metal layer ML4 disposed under the third metal layer ML3. When the first electrode 102 is formed of the first metal layer ML1, the second metal layer ML2, the third metal layer ML3, and the fourth metal layer ML4, the first electrode 102 may be deposited in the order of the fourth metal layer ML4→the third metal layer ML3→the second metal layer ML2→the first metal layer ML1, and then patterned by performing a photolithography process and an etching process.

The first metal layer ML1 may be disposed in contact with a lower portion of the bonding pattern 110 and electrically connected to the bonding pattern 110.

Further, the first metal layer ML1 may include a transparent conductive oxide layer such as indium tin oxide (ITO) or indium zinc oxide (IZO) which has an excellent adhesive strength and is corrosion and acid resistant. Here, the first metal layer ML1 may be referred to as an adhesive layer.

The second metal layer ML2 may be formed of a material having a different resistance value from the first metal layer ML1 and the third metal layer ML3. In this case, the second metal layer ML2 may be formed of a material having a lower light reflectivity but a higher resistance value than the third metal layer ML3. For example, the second metal layer ML2 may include titanium (Ti) or molybdenum (Mo).

The third metal layer ML3 may be formed of a material having a higher light reflectivity than the first metal layer ML1. In this case, the third metal layer ML3 may be formed of a material having a higher light reflectivity than the second metal layer ML2. For example, the third metal layer ML3 may include aluminum (Al) or silver (Ag).

That is, the light reflectivity of the third metal layer ML3 may be higher than the light reflectivity of each of the first metal layer ML1 and the second metal layer ML2.

The fourth metal layer ML4 may be formed of the same material as the second metal layer ML2. For example, the fourth metal layer ML4 may include titanium (Ti) or molybdenum (Mo).

The first metal layer ML1, the second metal layer ML2, the third metal layer ML3, and the fourth metal layer ML4 may be sequentially deposited and then patterned by performing a photolithography process and an etching process.

The passivation layer 120 may be disposed on the first electrode 102 and the signal line TL and include an opening hole 120a which exposes the bonding pattern 110.

The light-emitting element 100 may include a first conductivity-type semiconductor layer 140, an active layer 142 disposed on the first conductivity-type semiconductor layer 140, and a second conductivity-type semiconductor layer 144 disposed on the active layer 142. The first driving electrode 146 may be disposed under the first conductivity-type semiconductor layer 140, and a second driving electrode 148 may be disposed on the second conductivity-type semiconductor layer 144.

The light-emitting element 100 may be formed on a silicon wafer using a method such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), sputtering, or the like.

The first conductivity-type semiconductor layer 140 may be implemented with a compound semiconductor of group III-V, group II-VI, or the like and may be doped with a first dopant. The first conductivity-type semiconductor layer 140 may be formed of any one or more selected from semiconductor materials having a composition formula of Alₓ₁In_{y1}Ga_{(1-x1-y1)}N (0<=x1<=1, 0<=y1<=1, and 0<=x1+y1<=1), InAlGaN, AlGaAs, GaP, GaAs, GaAsP, and AlGaInP, but is not limited thereto. When the first dopant is an n-type dopant such as Si, Ge, Sn, Se, Te, or the like, the first conductivity-type semiconductor layer 140 may be an n-type nitride semiconductor layer. However, when the first dopant is a p-type dopant, the first conductivity-type semiconductor layer 140 may be a p-type nitride semiconductor layer.

The active layer 142 is a layer in which electrons (or holes) injected through the first conductivity-type semiconductor layer 140 and holes (or electrons) injected through the second conductivity-type semiconductor layer 144 meet. As the electrons and the holes recombine, the active layer 142 transitions to a lower energy level and may generate light having a wavelength corresponding thereto.

The active layer 142 may have any one structure among a single well structure, a multiple well structure, a single quantum well structure, a multi quantum well (MQW) structure, a quantum dot structure, and a quantum line structure, but the structure of the active layer 142 is not limited thereto. The active layer 142 may generate light in the visible light wavelength band. For example, the active layer 142 may output light in any one of the blue, green, and red wavelength bands.

The second conductivity-type semiconductor layer 144 may be disposed on the active layer 142. The second conductivity-type semiconductor layer 144 may be implemented with a compound semiconductor of group III-V, group II-VI, or the like, and may be doped with a second dopant. The second conductivity-type semiconductor layer 144 may be formed of any one selected from semiconductor materials having a composition formula of Inₓ₂Al_{y2}Ga_{1-x2-y2}N (0<=x2<=1, 0<=y2<=1, and 0<=x2+y2<=1), AlInN, AlGaAs, GaP, GaAs, GaAsP, and AlGaInP, but is not limited thereto. When the second dopant is a p-type dopant such as Mg, Zn, Ca, Sr, Ba, or the like, the second conductivity-type semiconductor layer 144 doped with the second dopant may be a p-type semiconductor layer. However, when the second dopant is an n-type dopant, the second conductivity-type semiconductor layer 144 may be an n-type nitride semiconductor layer.

In the embodiment, although a vertical structure in which the driving electrodes 146 and 148 are disposed at the top and bottom of a light-emitting structure is described, the light-emitting element may have a lateral structure or flip chip structure in addition to the vertical structure.

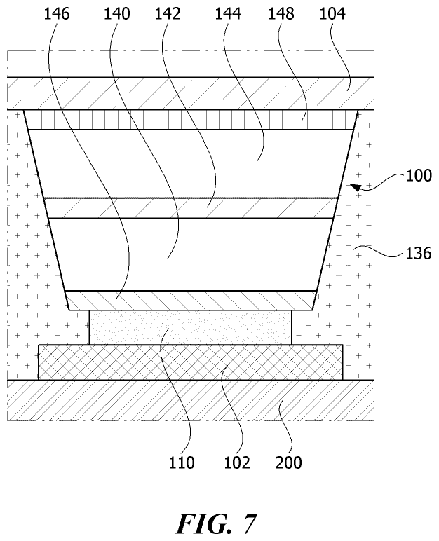

Hereinafter, a display device composed of micro light-emitting diodes (LEDs) according to one embodiment of the present specification will be described with reference to FIGS. 7 to 10.

FIG. 7 is a cross-sectional view illustrating a substrate connection structure of the light-emitting element constituting the display device according to one embodiment of the present specification.

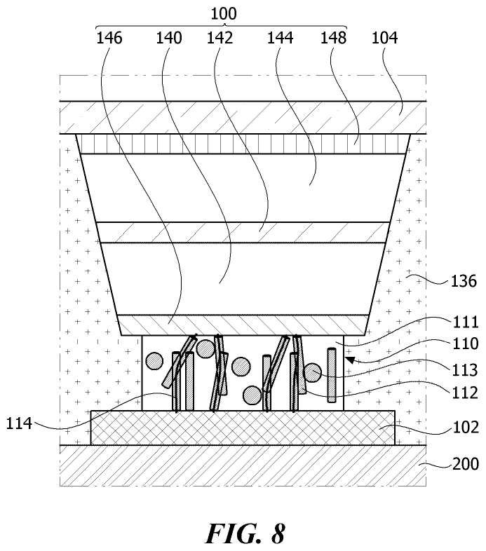

FIG. 8 is an enlarged cross-sectional view illustrating the bonding pattern in the substrate connection structure of the light-emitting element constituting the display device according to one embodiment of the present specification.

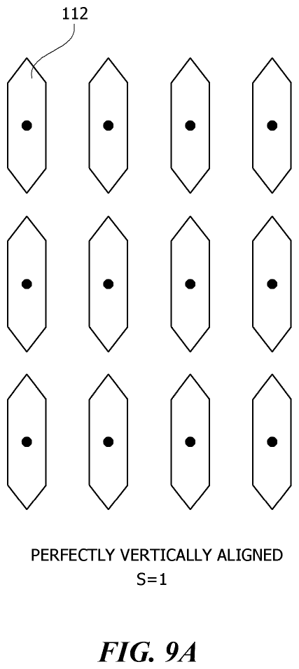

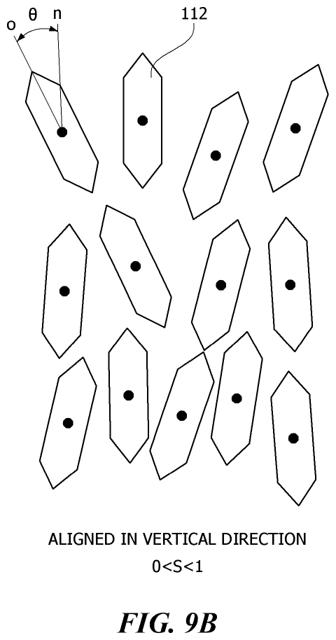

FIGS. 9A-9C are views illustrating a vertical alignment and orientation state of conductive particles in the bonding pattern of FIG. 8, wherein FIG. 9A is a view illustrating a perfectly vertically aligned state (S=1), FIG. 9B is a view illustrating an aligned state in a vertical direction at a certain angle (θ)(0<S<1), and FIG. 9C is a view illustrating an unaligned state (S=0).

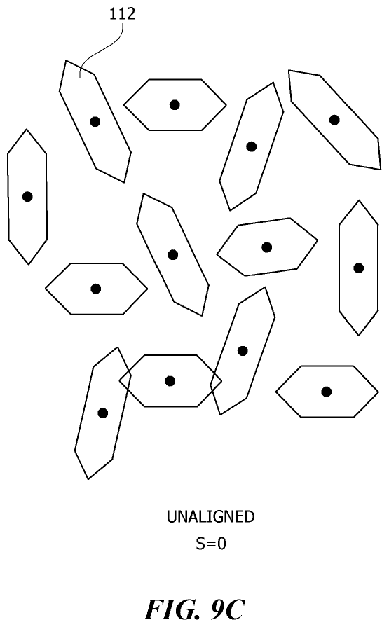

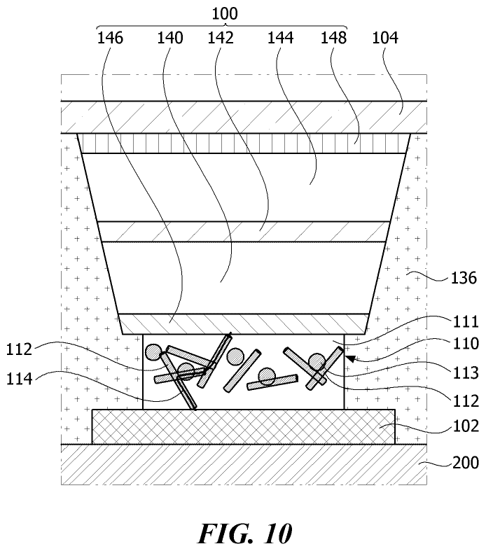

FIG. 10 is an enlarged cross-sectional view illustrating a bonding pattern in a substrate connection structure of a light-emitting element constituting a display device according to another embodiment of the present specification.

Referring to FIGS. 7 and 8, the display device according to one embodiment of the present specification includes a substrate 200, a plurality of first electrodes 102 disposed on the substrate 200, a plurality of bonding patterns 110 respectively disposed corresponding to upper portions of the plurality of first electrodes 102 and including conductive particles with an aspect ratio of 50 or more, a plurality of light-emitting elements 100 respectively disposed on the plurality of bonding pattern 110 to be electrically connected to the plurality of first electrodes 102, respectively, and a second electrode 104 disposed on the plurality of light-emitting elements 100 to be electrically connected to the plurality of light-emitting elements 100.

The substrate 200 is a line substrate on which the first electrodes 102 are disposed and may be composed of plastic having flexibility. For example, the substrate 200 may be fabricated as a single-layer or multi-layer substrate composed of a material selected from polyimide, polyethylene terephthalate, polyethylene naphthalate, polycarbonate, polyethersulfone, polyarylate, polysulfone, and a cyclic-olefin copolymer, but is not limited thereto. For example, the substrate 200 may be a ceramic substrate or glass substrate.

A pixel driving circuit (not shown, 201 in FIG. 4) may be disposed on the substrate 200. The pixel driving circuit 201 may include a plurality of thin film transistors using an amorphous silicon semiconductor, a polycrystalline silicon semiconductor, or an oxide semiconductor.

The pixel driving circuit 201 may include at least one driving thin film transistor, at least one switching thin film transistor, and at least one storage capacitor. The pixel driving circuit 201 may be formed on the substrate 200 through a process of fabricating a thin film transistor (TFT) when including a plurality of thin film transistors. In the embodiment, the pixel driving circuit 201 may be a concept that collectively refers to a plurality of thin film transistors electrically connected to the light-emitting elements 100.

The pixel driving circuit 201 may be a driving driver fabricated on a single crystal semiconductor substrate 200 using a process of fabricating a metal-oxide-silicon field effect transistor (MOSFET). The driving driver may include a plurality of pixel driving circuits to drive a plurality of sub-pixels. When the pixel driving circuit 201 is implemented as a driving driver, after an adhesive layer is disposed on the substrate 200, the driving driver may be mounted on the adhesive layer through a transfer process.

A buffer layer (not shown, 202 in FIG. 4) which covers the pixel driving circuit 201 may be disposed on the substrate 200. The buffer layer 202 may be composed of an organic insulating material, for example, photosensitive photo acryl or photosensitive polyimide, but is not limited thereto.

An insulating layer (not shown, 204 in FIG. 4) may be disposed on the buffer layer 202. The insulating layer 204 may be composed of an organic insulating material, for example, photosensitive photo acryl or photosensitive polyimide, but is not limited thereto.

Connection lines (not shown) may be disposed on the buffer layer 202. The connection lines may include a plurality of connection lines such as a first connection line (RT1 in FIG. 5), a second connection line (RT2 in FIG. 5), and the like. The connection lines may be connected to the corresponding signal lines (TL1 to TL6 in FIG. 5) or connected to signal lines TL.

A plurality of bank patterns (108 in FIG. 5) may be disposed on the insulating layer 204. The bank pattern 108 may be composed of an organic insulating material, for example, photosensitive photo acryl or photosensitive polyimide, but is not limited thereto. The bank pattern 108 may guide a position where the light-emitting elements 100 will be attached in the transfer process of the light-emitting elements 100. Further, the bank pattern 108 may also be omitted.

The first electrode 102 is located on the substrate 200 and may be formed as a bar-shaped electrode which is long in one direction. The first electrode 102 may be configured to function as a data electrode.

The first electrode 102 may include a single layer or multi-layer metal layer selected from titanium (Ti), molybdenum (Mo), and aluminum (Al). However, the present specification is not limited thereto.

Referring to FIG. 8, the bonding pattern 110 is disposed on the first electrode 102. The bonding pattern 110 may include conductive particles include a conductive particle material 112 with a large aspect ratio and a photosensitive resin 111 to improve the connection reliability between a first driving electrode 146 which is a lower electrode of the light-emitting element 100 and the first electrode 102 of the substrate.

The photosensitive resin 111 includes a binder, and the binder may include negative type and positive type binders.

The conductive particles may include a conductive particle material 112 with a large aspect ratio and a conductive filler 113 or may include a conductive particle material 112 with a large aspect ratio.

Here, the conductive filler 113 may include metal-based or carbon-based conductive materials. The metal-based conductive materials may include a CNT, Ag, an Ag nanowire, and the like. However, the present specification is not limited thereto. The carbon-based conductive materials may include spherical carbon black, carbon nanotubes, carbon fibers, and graphene. However, the present specification is not limited thereto.

The conductive particle with a large aspect ratio may include a conductive particle material 112 with an aspect ratio of 50 to 1000 or more. In some embodiments, the conductive particles having conductive particle materials with an aspect ratio of 300 to 500 or more may be preferred. The materials with an aspect ratio of 300 to 500 or more include a carbon fiber and an Ag nanowire. The plurality of light-emitting elements 100 are respectively transferred and disposed on the bonding patterns 110.

Accordingly, as a conductive path 114 is formed by the conductive particle materials 112 with a large aspect ratio and the conductive fillers 113 in the bonding pattern 110, the light-emitting element 100 is electrically connected to the electrode 102 through the conductive path 114.

The light-emitting element 100 may include a first conductivity-type semiconductor layer 140, an active layer 142 disposed on the first conductivity-type semiconductor layer 140, and a second conductivity-type semiconductor layer 144 disposed on the active layer 142. The first driving electrode 146 may be disposed under the first conductivity-type semiconductor layer 140, and a second driving electrode 148 may be disposed on the second conductivity-type semiconductor layer 144.

The first conductivity-type semiconductor layer 140 may be implemented with a compound semiconductor of group III-V, group II-VI, or the like and may be doped with a first dopant. The first conductivity-type semiconductor layer 140 may be formed of any one or more selected from semiconductor materials having a composition formula of Alₓ₁In_{y1}Ga_{(1-x1-y1)}N (0<=x1<=1,0<=y1<=1, and (<=x1+y1<=1), InAlGaN, AlGaAs, GaP, GaAs, GaAsP, and AlGaInP, but is not limited thereto. When the first dopant is an n-type dopant such as Si, Ge, Sn, Se, Te, or the like, the first conductivity-type semiconductor layer 140 may be an n-type nitride semiconductor layer. However, when the first dopant is a p-type dopant, the first conductivity-type semiconductor layer 140 may be a p-type nitride semiconductor layer.

The active layer 142 is a layer in which electrons (or holes) injected through the first conductivity-type semiconductor layer 140 and holes (or electrons) injected through the second conductivity-type semiconductor layer 144 meet. As the electrons and the holes recombine, the active layer 142 transitions to a lower energy level, and may generate light having a wavelength corresponding thereto.

The active layer 142 may have any one structure among a single well structure, a multiple well structure, a single quantum well structure, a multi quantum well (MQW) structure, a quantum dot structure, and a quantum line structure, but the structure of the active layer 142 is not limited thereto. The active layer 142 may generate light in the visible light wavelength band. For example, the active layer 142 may output light in any one of the blue, green, and red wavelength bands.

The second conductivity-type semiconductor layer 144 may be disposed on the active layer 142. The second conductivity-type semiconductor layer 144 may be implemented with a compound semiconductor of group III-V, group II-VI, or the like, and may be doped with a second dopant. The second conductivity-type semiconductor layer 144 may be formed of any one selected from semiconductor materials having a composition formula of Inₓ₂Al_{y2}Ga_{1-x2-y2}N(0<=x2<=1, 0<=y2<=1, and 0<=x2+y2<=1), AlInN, AlGaAs, GaP, GaAs, GaAsP, and AlGaInP, but is not limited thereto. When the second dopant is a p-type dopant such as Mg, Zn, Ca, Sr, Ba, or the like, the second conductivity-type semiconductor layer 144 doped with the second dopant may be a p-type semiconductor layer. However, when the second dopant is an n-type dopant, the second conductivity-type semiconductor layer 144 may be an n-type nitride semiconductor layer.

In the embodiment, although a vertical structure in which the driving electrodes 146 and 148 are disposed at the top and bottom of the light-emitting structure is described, the light-emitting element may have a lateral structure or flip chip structure in addition to the vertical structure.

The plurality of light-emitting elements 100 are electrically connected to the first electrodes 102 by the conductive bonding patterns 110. The first driving electrode 146 of the light-emitting element 100 is electrically connected to the first electrode 102 through the conductive path 114 generated by the conductive particle materials 112 with a large aspect ratio in the bonding pattern 110.

The second electrode 104 is disposed on the plurality of the light-emitting elements 100. As the second driving electrodes 148 of the light-emitting elements 100 are in contact with the second electrode 104, the light-emitting elements 100 are electrically connected to the second electrode 104.

FIG. 9A is a case where a vertical electric field is applied and thus a vertical alignment degree(S) of the conductive particles 112 in the bonding pattern 110 is 1.

In this case, the vertical alignment degree(S) of the conductive particles 112 may be defined as follows.

$$S = 1 / 2 ( 3 < cos 2 θ > - 1 )$$

Here, ‘θ’ is an angle between a conductive particle axis and a director (90°), and ‘<cos 2θ>’ is a volume average.

Since the vertical alignment degree(S) is 1 in FIG. 9A, even when a content of the conductive particles 112 with an aspect ratio of about 300 to 500 or more is 3 wt % or more, the light-emitting element 100 may be electrically connected to the first electrode 102 through the conductive path 114 generated by the vertically aligned conductive particles 112.

FIG. 9B is a case where the vertical electric field is applied and thus the vertical alignment degree(S) of the conductive particles 112 in the bonding pattern 110 is 0<S<1.

Since the vertical alignment degree(S) in FIG. 9B is smaller compared to FIG. 9A, when a content of the conductive particles 112 with an aspect ratio of about 300 or more is 5 wt % or more, the light-emitting element 100 may be electrically connected to the first electrode 102 through the conductive path 114 generated by the conductive particles 112.

Specifically, as shown in FIG. 9B, the conductive path 114 may be formed even when the vertical alignment degree(S) is only about 0.1, but when the vertical alignment degree(S) is 0.3 or more, the conductive path 114 may be easily formed.

FIG. 9C is a case where the vertical electric field is not applied and thus the vertical alignment degree(S) of the conductive particles 112 in the bonding pattern 110 is 0.

Referring to FIGS. 9C and 10, since the vertical alignment degree(S) of the conductive particles 112 is 0, that is, the conductive particles 112 with an aspect ratio of 300 to 500 or more are randomly distributed in the bonding pattern, the conductive path 114 may not be easily generated by the conductive particles 112. However, when the content of the conductive particles 112 with an aspect ratio of 300 or more is increased to 7 wt % or more, as the conductive path 114 is formed by the conductive particles 112, the light-emitting element 100 may be electrically connected to the first electrode 102.

Thus, when rod-type conductive particles, that is, the conductive particles with an aspect ratio of 300 or more (112 in FIG. 8) and the carbon-based conductive filler (113 in FIG. 8) are arranged in the vertical direction, a desired low-resistance property may be acquired even when lowering a content ratio of the conductive particles compared to a case where the conductive particles 112 and the conductive fillers 113 are randomly arranged.

Accordingly, lowering the content ratio of the conductive particles in the bonding pattern 110 helps to miniaturize of the pattern and allows a mass production process of display device products to be stably performed.

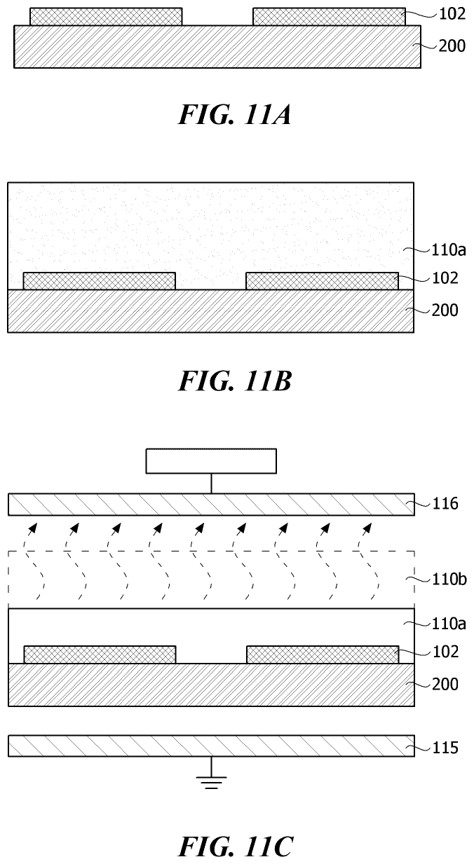

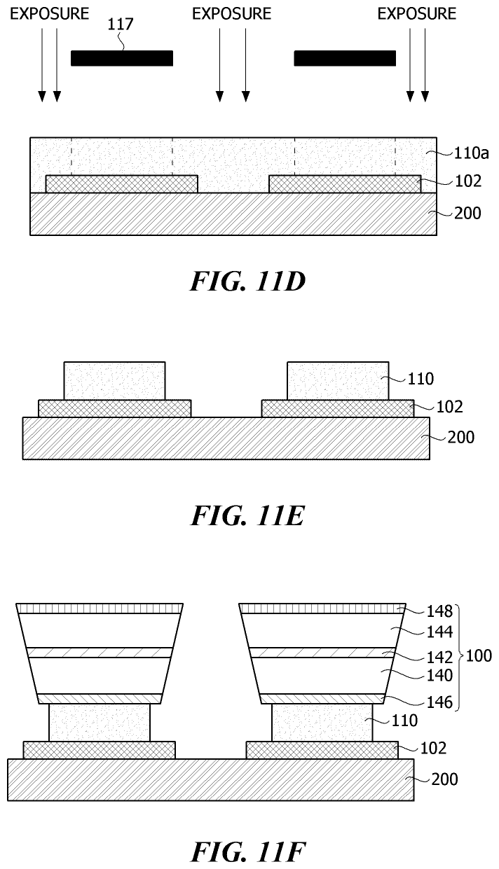

Hereinafter, a method of fabricating a display device composed of micro LEDs according to one embodiment of the present specification will be described with reference to FIGS. 11A to 11F.

FIGS. 11A to 11F are views illustrating a substrate connection process of light-emitting elements constituting a display device according to one embodiment of the present specification

In a process of fabricating the display device according to one embodiment of the present specification, before a process of forming electrodes 102 on a substrate 200, since processes of forming a pixel driving circuit (201 in FIG. 4), a buffer layer (202 in FIG. 4), an insulating layer (204 in FIG. 4), and bank patterns (108 in FIG. 4) on the substrate 200 are described as in FIGS. 4 to 6, the description thereof will be omitted herein.

Referring to FIG. 11A, an electrode layer (not shown) is formed on the substrate 200 and then is selectively removed through a mask process using a photolithography technology to form the electrode 102.

The substrate 200 may be composed of plastic having flexibility. For example, the substrate 200 may be fabricated as a single-layer or multi-layer substrate composed of a material selected from polyimide, polyethylene terephthalate, polyethylene naphthalate, polycarbonate, polyethersulfone, polyarylate, polysulfone, and a cyclic-olefin copolymer, but is not limited thereto. For example, the substrate 200 may be a ceramic substrate or glass substrate.

The electrode layer (not shown) for forming the electrode 102 may contain copper, aluminum, titanium (Ti), molybdenum (Mo), gold, silver, and platinum components with high conductivity, or may include a single layer or multi-layer metal layer selected from conductive electrode materials such as indium tin oxide (ITO) and the like. However, the present specification is not limited thereto. The first electrode 102 or signal lines TL may be formed to have a metal stack structure in which a plurality of metal layers are formed using metal materials of different materials, thicknesses, and the like.

Next, referring to FIG. 11B, a bonding layer 110a is formed on the substrate 200 including the electrode 102.

The bonding layer 110a may include conductive particles including a conductive particle material (112 in FIG. 8) with a large aspect ratio and a photosensitive resin (111 in FIG. 8) to improve the connection reliability between a first driving electrode (not shown, 146 in FIG. 4) which is a lower electrode of a light-emitting element 100 and the first electrode 102 of the substrate.

In this case, since the bonding layer 110a includes the photosensitive resin 111, a patterning process by a photolithography process is possible. Accordingly, since the bonding layer 110a does not require a separate process of forming a photoresist to perform the patterning process, the fabrication process may be reduced.

Furthermore, since a bonding layer material does not remain in a region other than an electrode connection portion during the patterning process by the photolithography process, the bonding layer 110a does not affect a subsequent coating process.

The photosensitive resin 111 includes a binder, and the binder may include negative type and positive type binders.

The conductive particles may include a conductive particle material 112 with a large aspect ratio and a conductive filler 113 or may include a conductive particle material 112 with a large aspect ratio.

Here, the conductive filler 113 may include metal-based or carbon-based conductive materials. The metal-based conductive materials may include a CNT, Ag, an Ag nanowire, and the like. However, the present specification is not limited thereto.

The carbon-based conductive materials may include spherical carbon black, carbon nanotubes, carbon fibers, and graphene. However, the present specification is not limited thereto.

The conductive particle with a large aspect ratio may include a conductive particle material 112 with an aspect ratio of 50 to 1000 or more. Specifically, the conductive particle including a conductive particle material with an aspect ratio of 300 to 500 or more may be preferred in some embodiments.

Next, referring to FIG. 11C, separate ground electrodes 115 and 116 may be disposed outside the substrate 200 to apply an electric field in a vertical direction. Alternatively, electrode lines (not shown) formed on the substrate 200 may be grounded.

In this case, a voltage for applying the electric field in the vertical direction may be variably applied in proportion to the viscosity of the photosensitive resin solution.

The electric field may be applied in a range of about +5 to 50 kV/cm. However, the present specification is not necessarily limited thereto. An array in the vertical direction may be formed by applying an electric field of about +5 to 50 kV/cm in the vertical direction which is an up and down direction. In this case, the vertical array of the conductive particles has a range of 0<S<1. Here, S means an alignment degree in the vertical direction.

A partial thickness 100b of the bonding layer 110a is removed by subjecting the bonding layer 110a to a vacuum chamber dry (VDC) process and then evaporating a solvent in the bonding layer 110a through a soft bake process.

Next, referring to FIG. 11D, a partial region of the bonding layer 110a located in a region where the electrode is not formed is exposed by performing an exposure process in a state of aligning an exposure mask 117 at a certain distance above the bonding layer 110a.

Next, referring to FIG. 11E, the bonding pattern 110 is formed by removing the exposed region of the bonding layer 110a through development and hard bake processes. In this case, the bonding pattern 110 remains only on the electrode 102 of the substrate 200.

Next, referring to FIG. 11F, a process of disposing the light-emitting element 100 on the substrate 200 is completed by transferring and disposing a grown light-emitting element 100 on the bonding pattern 110.

The light-emitting element 100 may include a first conductivity-type semiconductor layer 140, an active layer 142 disposed on the first conductivity-type semiconductor layer 140, and a second conductivity-type semiconductor layer 144 disposed on the active layer 142. A first driving electrode 146 may be disposed under the first conductivity-type semiconductor layer 140, and a second driving electrode 148 may be disposed on the second conductivity-type semiconductor layer 144.

In this case, the first driving electrode 146 of the light-emitting element 100 is electrically connected to the electrode 102 formed on the substrate 200 through the bonding pattern 110. Specifically, since the first driving electrode 146 of the light-emitting element 100 is brought into contact with the electrode 102 on the substrate 200 by the plurality of conductive particles 112 vertically aligned in the bonding pattern 110, the light-emitting element 100 is electrically connected to the electrode 102 of the substrate 200.

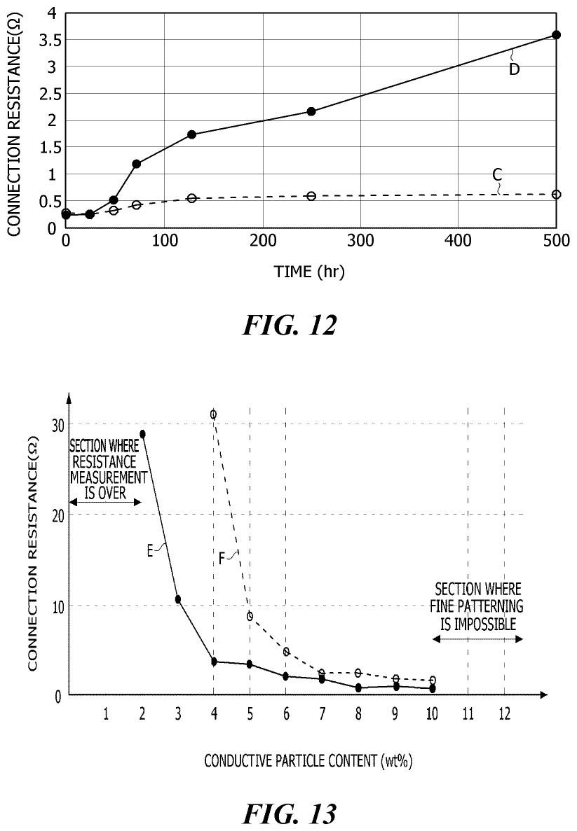

FIG. 12 is a view illustrating the connection resistance according to materials constituting the bonding pattern in a substrate connection structure of the display device according to one embodiment of the present specification.

‘C’ in FIG. 12 represents a case where the bonding pattern in the embodiment according to the present specification contains spherical carbon black and carbon nanotubes at 50:50 wt %.

Further, ‘D’ in FIG. 12 represents a case where the bonding pattern is formed using only spherical carbon black.

FIG. 12 is a graph of the results in which contact resistance is measured by performing bonding for two seconds at 140° C./10 MPa, and a measurement sample is remeasured over time in a chamber of 80° C./85% RH.

Referring to FIG. 12, as shown in ‘C’ which is an embodiment of the present specification, it can be seen that the connection resistance (Ω) is maintained constant at 0.5Ω over time. On the other hand, in a case of ‘D’ which is a comparative example, it can be seen that the connection resistance (Ω) continuously increases from 0.5Ω to 3.5 (Ω) over time.

Accordingly, as shown in the embodiment of the present specification, when the conductive particles in the bonding pattern 110 contain spherical carbon black and carbon nanotubes at 50:50 wt %, as the connection resistance is maintained constant at 0.5Ω, the reliability of the electrode connection of a micro LED chip may be improved.

FIG. 13 is a view illustrating the connection resistance according to the content of the conductive particles in the bonding pattern in the substrate connection structure of the display device according to one embodiment of the present specification.

‘E’ in FIG. 13 is a case where vertical alignment of the conductive particles in the bonding pattern is applied, and is a result which shows the connection resistance when the content of conductive particles is 3 wt % or more. Specifically, ‘E’ in FIG. 13 is a case where a vertical alignment degree(S) of the conductive particles is about 0.6, an aspect ratio is about 400, and a content ratio of spherical carbon black and carbon nanotubes is 50:50 wt %.

On the other hand, ‘F’ in FIG. 13 is a case where the vertical alignment of the conductive particles in the bonding pattern is not applied, and is a result which shows the connection resistance when the content of conductive particles is 5 wt % or more. Specifically, ‘F’ in FIG. 13 is a case where a content ratio of spherical carbon black and carbon nanotubes is 50:50 wt %.

As shown in ‘E’ in FIG. 13, it can be seen that stable low resistance formation of the bonding pattern is possible even when the content of conductive particles is 3 wt % or more because the conductive particles of the bonding pattern 110 are vertically aligned.

As shown in ‘F’ in FIG. 13, it can be seen that the stable low resistance of the bonding pattern can be formed only when the content of conductive particles is 5 wt % or more because the conductive particles of the bonding pattern 110 are not vertically aligned.

Further, it can be seen that the resistance may be excessively measured when the content of the conductive particles is less than 3 wt %, and fine patterning may be difficult when the content of the conductive particles exceeds about 10 wt %.

Thus, referring to FIG. 13, when rod-type conductive particles, that is, conductive particle materials with an aspect ratio of 300 or more (112 in FIG. 8) are arranged in the vertical direction, a desired low-resistance property may be acquired even when lowering a content ratio of the conductive particles compared to a case where the conductive particles are randomly arranged.

Accordingly, in one embodiment of the present specification, lowering the content ratio of the conductive particles of the bonding pattern helps to miniaturize the pattern, and allows a mass production process of display device products to be stably performed.

Further, since the conductive particles in the bonding pattern 110 are composed of a conductive particle material with an aspect ratio of 300 or more, it is quite possible to electrically connect the light-emitting element 100 to the electrode 102 on the substrate 200 through the bonding pattern even when the vertical alignment degree(S) of the conductive particles is only about 0.1

In addition, in the embodiment of the present specification, the light-emitting element 100 may be electrically connected to the electrode 102 on the substrate 200 in an excellent manner through the bonding pattern when the vertical alignment degree(S) of the conductive particles is 0.3 or more.

According to the present specification, as an electrode connection material including conductive particles with a large aspect ratio is used, the connection reliability between an electrode of a substrate and a microelectrode of a light-emitting element is improved, and thus it is possible to mount an electronic component including light-emitting elements with a narrow electrode spacing.

According to the present specification, as an electrode connection material including conductive particles that are spherical and have a large aspect ratio, it is possible to prevent inter-particle contact defects which can occur due to expansion of organic materials under reliability conditions.

According to the present specification, as a resin material including conductive particles with a large aspect ratio can be photo-patterned and thus no material remains in a region other than an electrode connection portion, a subsequent coating process is not affected.

According to the present specification, since it is possible to form a bonding pattern by a photolithography process using a resin material including conductive particles with a large aspect ratio, process costs can be reduced by simplifying a fabrication process.

The display device according to various embodiments of the present disclosure may be described as follows.

A display device may comprise a substrate; a first electrode disposed on the substrate; a bonding pattern disposed on the first electrode and including a plurality of conductive particles with an aspect ratio of 50 or more; a light-emitting element disposed on the bonding pattern and electrically connected to the first electrode through the bonding pattern; and a second electrode disposed on the light-emitting elements.

According to one embodiment of the present disclosure, the bonding pattern may include a photosensitive resin and a conductive filler.

According to one embodiment of the present disclosure, the conductive filler may include metal-based and carbon-based conductive materials.

According to one embodiment of the present disclosure, the metal-based conductive materials may include a CNT, Ag, and an Ag nanowire, and the carbon-based conductive materials include carbon black, carbon nanotubes, carbon fibers, and graphene.

According to one embodiment of the present disclosure, the bonding pattern may include a plurality of conductive particles with an aspect ratio of 300 or more.

According to one embodiment of the present disclosure, the bonding pattern may include 3 wt % or more of the plurality of conductive particles with an aspect ratio of 300 or more.

According to one embodiment of the present disclosure, the light-emitting element may be connected to the electrode through a conductive path between the conductive particles in the bonding pattern.

According to one embodiment of the present disclosure, the light-emitting element may be a micro light emitting diode.

According to one embodiment of the present disclosure, the light-emitting element may include a first conductivity-type semiconductor layer; an active layer disposed on the first conductivity-type semiconductor layer; a second conductivity-type semiconductor layer disposed on the active layer; a first driving electrode disposed under the first conductivity-type semiconductor layer; and a second driving electrode disposed on the second conductivity-type semiconductor layer.

A method of fabricating a display device according to one embodiment of the present disclosure may comprise forming a first electrode on a substrate; forming a bonding pattern including a plurality of conductive particles with an aspect ratio of 50 or more on the first electrode; disposing a light-emitting element on the bonding pattern and electrically connecting the light-emitting element to the first electrode through the bonding pattern; and forming a second electrode on the light-emitting element.

According to one embodiment of the present disclosure, the forming of the bonding pattern may include a process of forming a bonding layer including a photosensitive resin and the conductive particles with an aspect ratio of 50 or more on the substrate including the electrodes; a process of applying a vertical electric field to the bonding layer; and a process of selectively removing the bonding layer through a photolithography process to form the bonding pattern on the electrode.

According to one embodiment of the present disclosure, the process of selectively removing the bonding layer through the photolithography process may include a process of selectively removing the bonding layer through exposure and development processes using a photomask without forming a separate photoresist on the bonding layer.

According to one embodiment of the present disclosure, the bonding pattern may include a photosensitive resin and a conductive filler.

According to one embodiment of the present disclosure, the conductive filler may include metal-based and carbon-based conductive materials.

According to one embodiment of the present disclosure, the metal-based conductive materials may include a CNT, Ag, and an Ag nanowire, and the carbon-based conductive materials include carbon black, carbon nanotubes, carbon fibers, and graphene.

According to one embodiment of the present disclosure, the bonding pattern may include 3 wt % or more of a plurality of conductive particles with an aspect ratio of 300 or more.

According to one embodiment of the present disclosure, the bonding pattern may include 3 wt % or more of a plurality of conductive particles with an aspect ratio of 300 or more when the conductive particles in the bonding pattern are vertically aligned.

According to one embodiment of the present disclosure, the bonding pattern may include 5 wt % or more of a plurality of conductive particles with an aspect ratio of 300 or more when the conductive particles in the bonding pattern are not vertically aligned and are in a random state.

According to one embodiment of the present disclosure, the light-emitting element may be a micro light emitting diode.

According to one embodiment of the present disclosure, the light-emitting element may include a first conductivity-type semiconductor layer; an active layer disposed on the first conductivity-type semiconductor layer; a second conductivity-type semiconductor layer disposed on the active layer; a first driving electrode disposed under the first conductivity-type semiconductor layer; and a second driving electrode disposed on the second conductivity-type semiconductor layer.

The effects of the present specification are not limited to the above-mentioned effects, and other effects which are not mentioned will be clearly understood by those skilled in the art from the description in claims.

Although embodiments of the present disclosure have been described in more detail with reference to the accompanying drawings, the present disclosure is not necessarily limited to the embodiments, and various modifications may be carried out without departing from the technical spirit of the present disclosure. Therefore, the embodiments disclosed in the present disclosure are not intended to limit the technical spirit of the present disclosure, but intended to describe the same, and the scope of the technical spirit of the present disclosure is not limited by these embodiments. Therefore, it should be understood that the above-described embodiments are illustrative and not restrictive in all respects.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate;
a first electrode on the substrate;
a bonding pattern on the first electrode, the bonding pattern including a plurality of conductive particles with an aspect ratio of 50 or more;
a light-emitting element on the bonding pattern, the light-emitting element electrically connected to the first electrode through the bonding pattern; and
a second electrode on the light-emitting element.

2. The display device of claim 1, wherein the bonding pattern includes a photosensitive resin and a conductive filler.

3. The display device of claim 2, wherein the conductive filler includes metal-based and carbon-based conductive materials.

4. The display device of claim 3, wherein the metal-based conductive materials include a CNT, Ag, and an Ag nanowire, and the carbon-based conductive materials include carbon black, carbon nanotubes, carbon fibers, and graphene.

5. The display device of claim 1, wherein the bonding pattern includes a plurality of conductive particles with an aspect ratio of 300 or more.

6. The display device of claim 5, wherein the bonding pattern includes 3 wt % or more of the plurality of conductive particles with an aspect ratio of 300 or more.

7. The display device of claim 1, wherein the light-emitting element is electrically connected to the first electrode through a conductive path between the plurality of conductive particles in the bonding pattern.

8. The display device of claim 1, wherein the light-emitting element is a micro light emitting diode.

9. The display device of claim 1, wherein the light-emitting element includes:
a first conductivity-type semiconductor layer;
an active layer on the first conductivity-type semiconductor layer;
a second conductivity-type semiconductor layer on the active layer;
a first driving electrode disposed under the first conductivity-type semiconductor layer; and
a second driving electrode on the second conductivity-type semiconductor layer.

10. A method of fabricating a display device, comprising:
forming a first electrode on a substrate;
forming a bonding pattern including a plurality of conductive particles with an aspect ratio of 50 or more on the first electrode;
disposing a light-emitting element on the bonding pattern and electrically connecting the light-emitting element to the first electrode through the bonding pattern; and
forming a second electrode on the light-emitting element.

11. The method of claim 10, wherein the forming of the bonding pattern includes:
forming a bonding layer including a photosensitive resin and the conductive particles with an aspect ratio of 50 or more on the substrate including the electrodes;
applying a vertical electric field to the bonding layer; and
selectively removing the bonding layer through a photolithography process to form the bonding pattern on the electrode.

12. The method of claim 11, wherein selectively removing the bonding layer through the photolithography process includes selectively removing the bonding layer through exposure and development processes using a photomask without forming a separate photoresist on the bonding layer.

13. The method of claim 10, wherein the bonding pattern includes a photosensitive resin and a conductive filler.

14. The method of claim 13, wherein the conductive filler includes metal-based and carbon-based conductive materials.

15. The method of claim 14, wherein the metal-based conductive materials include a CNT, Ag, and an Ag nanowire, and the carbon-based conductive materials include carbon black, carbon nanotubes, carbon fibers, and graphene.

16. The method of claim 10, wherein the bonding pattern includes 3 wt % or more of a plurality of conductive particles with an aspect ratio of 300 or more.

17. The method of claim 10, wherein the bonding pattern includes 3 wt % or more of a plurality of conductive particles with an aspect ratio of 300 or more when the conductive particles in the bonding pattern are vertically aligned.

18. The method of claim 10, wherein the bonding pattern includes 5 wt % or more of a plurality of conductive particles with an aspect ratio of 300 or more when the conductive particles in the bonding pattern are not vertically aligned and are in a random state.

19. The method of claim 10, wherein the light-emitting element is a micro light emitting diode.

20. The method of claim 10, wherein the light-emitting element includes:
a first conductivity-type semiconductor layer;
an active layer disposed on the first conductivity-type semiconductor layer;
a second conductivity-type semiconductor layer disposed on the active layer;
a first driving electrode disposed under the first conductivity-type semiconductor layer, and
a second driving electrode disposed on the second conductivity-type semiconductor layer.
